(19) United States
(12) Patent Application Publication
(10) Pub. No.: US 2005/0199972 A1
(43) Pub. Date: Sep. 15, 2005

(54) Bulk wave resonator and bulk wave filter

(76) Inventors: Hans Peter Lobl, MONSCHAU-IMGENBROICH (DE); Robert Frederick Milsom, Redhill, Surry (GB); Mareike Katharine Klee, Huckelhoven (DE); Rainer Kiewitt, Roetgen (DE); Christof Metzmacher, Aachen (DE)

Correspondence Address: Corporate Patent Counsel;Philips Electronics North America Corporation, P O Box 3001, Briarcliff Manor, NY, 10510, US

(21) Appl. No.: 10/514,588

(22) PCT Filed: May 15, 2003
(86) PCT No.: PCT/IB03/01883

§ 371 Date: Nov. 16, 2004

(30) Foreign Application Priority Data
May 20, 2002 (EP) 02253545.4

(51) Int. Cl. H01L 29/84

(52) U.S. Cl. 257/415; 257/416

(57) ABSTRACT

A bulk wave resonator comprising: a substrate (1); a layer (3) of piezoelectric material deposited on the substrate; a first electrode (2) and a second electrode (4) which are arranged on opposite surfaces of the layer (3) of piezoelectric material, the overlapping area of the first electrode (2) and second electrode (4) defining the resonance range of the bulk wave resonator, characterized in that the overlapping area in an intersecting plane parallel to at least one of the electrodes (2, 4) has an aspect ratio in the range from 1 (b/a) 100, where a is the length and b the width of the bulk wave resonator. The invention also relates to a bulk wave filter comprising such bulk wave resonators.

The invention relates to a bulk wave resonator comprising:
a substrate;
a layer of piezoelectric material deposited on the substrate;
a first electrode and a second electrode which are arranged on opposite surfaces of the layer of piezoelectric material, the overlapping area of first and second electrodes defining the resonance area of the bulk wave resonator. The invention particularly relates to a bulk wave filter which is constructed with such bulk wave resonators.

Bulk wave filters are used, for example, in the transmitting or receiving part of mobile telephones or base stations while minimizing the transit losses of the bulk wave filter is aimed for. Known measures to reach this comprise the use of piezo materials of high mechanical quality in the bulk wave resonators, which should also show low dielectric losses in an optimal construction of the reflectors and the use of acoustic low-loss materials in these reflectors to keep the acoustic losses small. Furthermore, a good electrical conductivity of the resonator electrodes and small acoustic losses in these electrodes are provided.

In addition, however, the form of the resonators is decisive for small losses. For example, U.S. Pat. No. 6,150,703 suggests reducing the acoustic losses in that the edges of the resonator electrodes are not running parallel. In this way undesired oscillation modes are suppressed.

It is an object of the invention to provide a further measure with which the passband losses of a filter constructed by bulk wave resonators can be reduced.

This object is achieved by a bulk wave resonator having the features of claim 1. A bulk wave filter constructed from such resonators is the object of claim 5, applications are defined in claim 10.

According to the invention there is provided in a bulk wave resonator as defined in the opening paragraph that the overlap area in a plane of intersection in parallel with at least one of the electrodes has an aspect ratio in the range from 1≦(b/a)≦100 where a is the length and b the width of the bulk wave resonator.

The length of the bulk wave resonator then relates to the dimension which runs in essence in the direction of the electric current flow from input to output of a bulk wave filter constructed from series and parallel resonators. The width is the dimension that is in essence perpendicular thereto.

The aspect ratio is preferably situated in the range from 1≦(b/a)≦50, is further preferably in the range from 2≦(b/a)≦50 and mostly preferably in the range from 2≦(b/a)≦8.

The absolute length or width of the bulk wave resonator depends on the operating frequency and the electrical impedance of the bulk wave filter which are to be attained. Typical values for a or b lie between one micrometer and several 100 micrometers.

A bulk wave filter has bulk wave resonators according to the intention at least one of which is arranged as a series resonator and at least one as a parallel resonator. Here the selection of the aspect ratio b/a according to the invention is particularly effective. The electric current in the bulk wave filter flows in the series resonators but preferably in the direction from input to output and in the parallel resonators perpendicularly thereto. An increase of the ratio reduces the resistance of the series resonators and thus the transit losses of the bulk wave filter are reduced. At the same time the electric series resistance of the electrodes of the parallel resonators is increased by the use of bulk wave resonators with a large aspect ratio. Since the parallel resonators in the passband of the bulk wave filter should block, thus should have a high electrical impedance, at the same time signal losses to ground are reduced via the parallel resonators.

Preferably, a bulk wave filter has a number of vo9lume wave resonators according to the invention which are reduced via the parallel resonators.

Preferably, a bulk wave filter has a number of bulk wave resonators according to the invention which are arranged mirror symmetrically with an axis running in the direction of the length a of the series resonators. As a result of this arrangement the electric current in the series resonators of the filter mainly has components in this direction.

Furthermore, it is also preferred to have the bond wires and flip chip bumps necessary for the connectors arranged mirror symmetrically to this axis. This fully suppresses the current components in the high-resistance direction b of the series resonators.

Furthermore, it is preferred to have various parallel resonators switched by series-arranged bulk wave resonators. The result of this is that one of the electrodes of the bulk wave resonators need not be contacted (floating electrode) and problems with contact resistors are eliminated.

Furthermore it is preferred to have various series resonators switched so that one of the electrodes of the bulk wave resonators need not be contacted (floating electrode) and problems with contact resistors are eliminated.

A bulk wave filter which is structured according to the invention may be used in a mobile telephone, a wirelessly communicating network or the like.

These and other aspects of the invention are apparent from and will be elucidated with reference to the embodiments described hereinafter.

In the drawings:

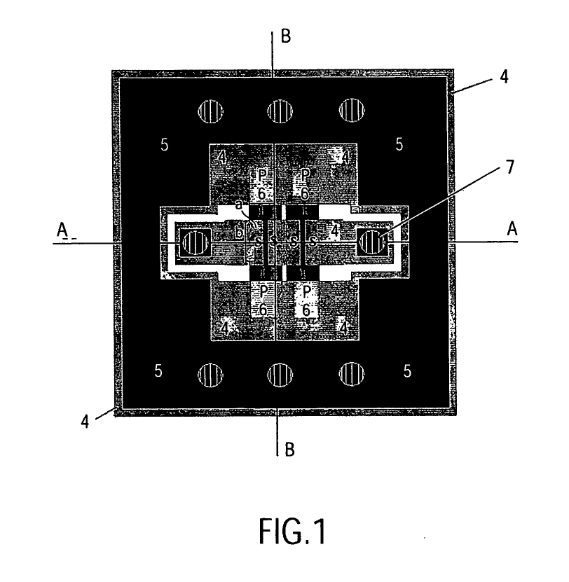

FIG. 1 shows a plan view of a bulk wave filter according to the invention;

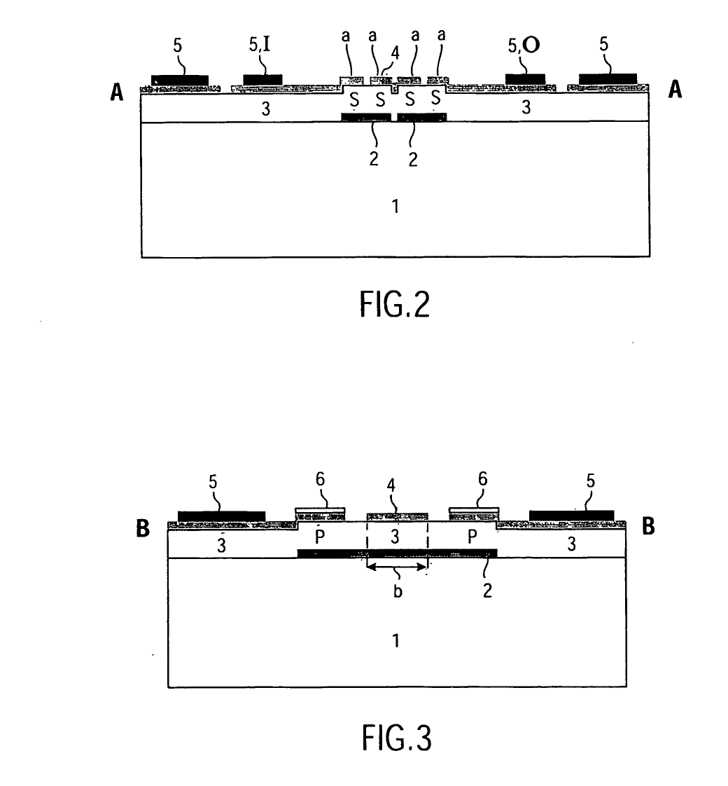

FIG. 2 shows a cross-section along the line A-A of FIG. 1;

FIG. 3 shows a cross-section along the line B-B of the FIG. 1; and

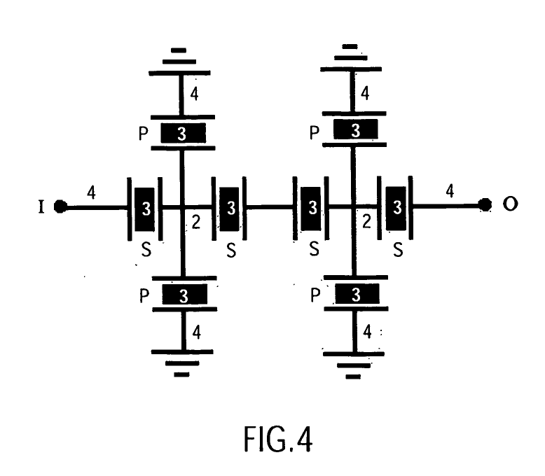

FIG. 4 shows a wiring diagram of the filter shown in FIG. 1.

FIG. 1 shows with the reference number 1 a substrate comprising silicon (Si), germanium (Ge), silicon germanium (Si—Ge), gallium arsenide (GaAs), aluminum oxide (Al₂O₃), glass or similar materials. Part of the substrate is also an acoustic reflector which consists of a multilayer structure of materials of changing height and low acoustic impedance. High acoustic impedance materials are, for example, tantalum oxide (Ta₂O₅), hafnium oxide (HfO₂), silicon nitride (Si₃N₄), aluminum nitride (AlN), tungsten (W) or titanium tungsten (TiW), which can be combined with silicon oxide (SiO₂) as a low acoustic impedance material. Alternatively, the acoustic reflector may also consist of a membrane of said materials or similar materials with an air gap beneath it. This membrane may, for example, also be generated by locally etching the substrate away. Series resonators S and parallel resonators P are interconnected on the substrate between input I and output O, which can be better seen in FIG. 4. In FIG. 1 the respective contact pads 5,I and 5,0 are shown. The substrate furthermore has an amplification layer 5 which does not only amplify the contact pads 5,I, 5,0 but also the grounding surface of the bulk wave filter. The amplification layer 5 usually is a well conductive material such as Al, Al:Cu, Al:Si, Cu, Mo, W. The layer 6 shown with the parallel resonators P is used for shifting the frequency of the parallel resonators P as a result of load to produce the filter curve. It preferably consists of a material having minor acoustic losses as already defined above. Series resonators S, parallel resonators P as well as flip chip bonds 7 and also bond wires (not shown) are arranged symmetrically relative to the axis A-A.

The structure of the series resonators S can be better seen in FIG. 2. On the substrate 1 are arranged sub-electrodes 2 which comprise Pt, Al, Al:Cu, Al:Si, Mo, W or combinations of these materials such as a primer layer of Ti, Cr, NiCr or the like. There is a piezoelectric layer 3 of AlN, ZnO, PZT, PLZT, KNbO₃ or similar materials on the substrate 1. Upper electrodes 4 are arranged on the piezoelectric layer 3 which electrodes may comprise the same materials as the lower electrodes 2. The series resonators S of the filter are defined by the overlap area between lower electrode 2 and an upper electrode 4. All series resonators S have an aspect ratio of width b to length a ranging from 1 to 100. As a result, the electrode resistance is minimized. On the upper electrodes 4 are finally arranged the contact pads 5,I, 5,0 as well as the amplification layer 5.

FIG. 3 shows that the parallel resonators are formed in analogous way. The references correspond to those of FIGS. 1 and 2.

FIG. 4 shows that both the series resonators S and the parallel resonators P as far as they are concerned are arranged as series combined resonators, so that the lower electrode 2 need not be contacted.

With the concept according to the invention a symmetrical filter structure having a very large aspect ratio and correspondingly low series resistance losses can be advantageously produced.

1. A bulk wave resonator comprising:
a substrate (1);
a layer (3) of piezoelectric material deposited on the substrate;
a first electrode (2) and a second electrode (4) which are arranged on opposite surfaces of the layer (3) of piezoelectric material, the overlapping area of the first electrode (2) and second electrode (4) defining the resonance range of the bulk wave resonator, characterized in that the overlapping area in an intersecting plane parallel to at least one of the electrodes (2, 4) has an aspect ratio in the range from 1≦(b/a)≦100, where a is the length and b the width of the bulk wave resonator.

2. A bulk wave resonator as claimed in claim 1, characterized in that the aspect ratio is in the range from 1≦(b/a)≦50.

3. A bulk wave resonator as claimed in claim 1, characterized in that the aspect ratio is situated in the range from 2≦(b/a)≦50.

4. A bulk wave resonator as claimed in claim 1, characterized in that the aspect ratio is situated in the range from 2≦(b/a)≦8.

5. A bulk wave filter comprising bulk wave resonators as claimed in claim 1 of which at least one is arranged as a series resonator (S) and at least one as a parallel resonator (P).

6. A bulk wave filter as claimed in claim 5, characterized in that a plurality of bulk wave resonators (S, P) are provided which are mirror symmetrically arranged in the direction of the length a of an axis (A/A) of a series resonator (S).

7. A bulk wave filter as claimed in claim 6, characterized in that the bond wires and flip chip bumps (7) are arranged mirror symmetrically with the axis (A/A).

8. A bulk wave filter as claimed in claim 5, characterized in that the interconnection of a plurality of parallel resonators (P) is effected by series-arranged bulk wave resonators.

9. A bulk wave filter as claimed in claim 5, characterized in that the series resonators (S) are connected so that an electrode need not be contacted (floating electrode).

10. The use of a bulk wave filter as claimed in claim 5 in a mobile telephone, a wireless communication network or the like.
